(19) United States
(12) Patent Application Publication
(10) Pub. No.: US 2024/0014174 A1
(43) Pub. Date: Jan. 11, 2024

(54) INTERFACE FOR A SEMICONDUCTOR CHIP WITH ADAPTIVE VIA REGION ARRANGEMENT AND SEMICONDUCTOR DEVICE WITH STACKED SEMICONDUCTOR CHIPS

(71) Applicants: Global Unichip Corporation, Hsinchu (TW); Taiwan Semiconductor Manufacturing Company, Ltd., Hsinchu (TW)

(72) Inventors: Yung-Chih Chen, Hsinchu (TW); Kun-Ti Lee, Hsinchu (TW); Chih-Kang Chiu, Hsinchu (TW); Igor Elkanovich, Hsinchu (TW)

(73) Assignees: Global Unichip Corporation, Hsinchu (TW); Taiwan Semiconductor Manufacturing Company, Ltd., Hsinchu (TW)

(21) Appl. No.: 17/858,056

(22) Filed: Jul. 5, 2022

(51) Int. Cl. H01L 25/065; H01L 23/00; H01L 23/48

(52) U.S. Cl. CPC H01L 25/0657; H01L 24/16; H01L 23/481; H01L 2224/32145; H01L 2924/15311; H01L 2225/06513; H01L 2225/06541

(57) ABSTRACT

An interface for a semiconductor chip provided herein includes bonds. The interface has device layout channels and via layout channels and including a circuitry and routing structure. Each device layout channel is located between two via layout channels in a first direction to form a unit layout channel extending in a second direction intersecting the first direction. The bonds are arranged in a bond map following the via layout channels and outside the device layout channels. Most adjacent two of the bonds in the second direction are arranged in a vertical pitch, two bonds at two opposite sides of the device layout channel in the first direction are arranged in a transversal pitch, and the transversal pitch is greater than the vertical pitch. A portion of the circuitry and routing structure is disposed in the device layout channels. A semiconductor device including stacked semiconductor chips is also provided.

### BACKGROUND

### Technical Field

The disclosure is related to an interface for a semiconductor chip and a semiconductor device with stacked semiconductor chips.

### Description of Related Art

The semiconductor industry continues to improve the integration density of various electronic components (e.g., transistors, diodes, resistors, capacitors, etc.). To further increase circuit density, three-dimensional integrated circuits (3D-ICs) have been investigated. Multiple semiconductor chips and/or wafers are stacked to achieve the three-dimensional integrated circuits, so that more electronic components can be integrated within a limited area to reach the high integration density. One technique of transmitting the electric signals and powers between the stacked semiconductor chips and/or wafers is accomplished by through-silicon vias (TSVs). The arrangement of the through-silicon vias forms bonds that is also a considerable factor to satisfy various integration requirements.

### SUMMARY

The disclosure is directed to an interface for a semiconductor chip that has an adaptive via region arrangement which improves the utilization of the layout spacing.

The disclosure is directed to a semiconductor device having good adaptivity for various bond density requirements.

In some embodiments, an interface for a semiconductor chip includes a plurality of bonds, and the interface has device layout channels and via layout channels. Each of the device layout channels is located between two of the via layout channels in a first direction to form a unit layout channel extending in a second direction intersecting the first direction. The bonds are in a bond map following the via layout channels and outside the device layout channels. Most adjacent two of the bonds in the second direction are arranged in a vertical pitch, two bonds at two opposite sides of the device layout channel in the first direction are arranged in a transversal pitch, and the transversal pitch is greater than the vertical pitch. The semiconductor chip includes a circuitry and routing structure including a plurality of routing patterns or a combination thereof, wherein at least a portion of the circuitry and routing structure is disposed in the device layout channels.

In some embodiments, a semiconductor device includes a plurality of semiconductor chips. One of the semiconductor chips is stacked to another of the semiconductor chips. Each of the semiconductor chips includes an interface for the semiconductor chip. The interface has device layout channels and via layout channels and the semiconductor chip include a circuitry and routing structure. The interface includes a plurality of bonds. Each of the device regions is located between two of the via regions in a first direction to form a unit block, and each of the unit blocks is arranged next to one another in a second direction intersecting the first direction. The bonds are arranged in a bond map following the via regions and outside the device regions. The bonds are arranged in a vertical pitch in the second direction, and the vertical pitch is substantially equal to a dimension of each of the unit blocks in the second direction. A portion of the circuitry and routing structure is disposed in the device regions.

In light of the foregoing, the interface for a semiconductor chip in accordance with the embodiments of the disclosure includes the unit blocks. Each of the unit blocks has one device region between two via regions in the first direction and the unit blocks are arranged in the second direction to form unit layout channels. The bonds are arranged in the via regions outside the device regions and the circuitry and routing structure is spaced from the bonds by a keep-out distance. As such, the device regions of the unit blocks form large device layout channels each extending in the second direction without interrupted by the bonds and the via regions of the unit blocks form the via layout channels. The configuration of the unit layout channels is applicable for various bond densities and helpful to keep layout resource if the bond pitch shrinks. Accordingly, the interface in the disclosure may be adaptive for various layout designs of the semiconductor device.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a drawing, schematically illustrating the 3D package structure of the semiconductor chips by face-to-face, face-to-back and back-to-back, according to an embodiment of the disclosure.

FIG. 2 schematically illustrates a plane view of an interface for a semiconductor chip in accordance with some embodiments of the disclosure.

FIG. 3 schematically illustrates a plane view of an interface for a semiconductor chip in accordance with some embodiments of the disclosure.

FIG. 4 schematically illustrates a plane view of an interface for a semiconductor chip in accordance with some embodiments of the disclosure.

FIG. 5 schematically illustrates an interface for a semiconductor chip in accordance with some embodiments of the disclosure.

FIG. 6 schematically illustrates an interface for a semiconductor chip in accordance with some embodiments of the disclosure.

FIG. 7 schematically illustrate a portion of a semiconductor chip in accordance with some embodiments of the disclosure.

### DESCRIPTION OF THE EMBODIMENTS

The disclosure is directed to an interface for a semiconductor device having stacked semiconductor chips, in which the interface is fabricated based on the 3D packaging technology. In the disclosure, the interface included in a semiconductor chip may include bonds exclusively arranged in via regions. The via regions are spaced by a transversal pitch in a first direction that is sufficient for keeping a device region for disposing a circuitry and routing structure and are closely arranged in a second direction in line to form a via layout channel. As such, the bonds may be arranged in the via layout channel with a predetermined smallest pitch in the second direction. The via region arrangement described in the disclosure facilitates better layout spacing utilization and the via region arrangement is adaptive for various bond density designs and various tacking manners of the 3D packaging technology.

Several embodiments are provided for describing the invention but the disclosure is not just limited to the embodiments.

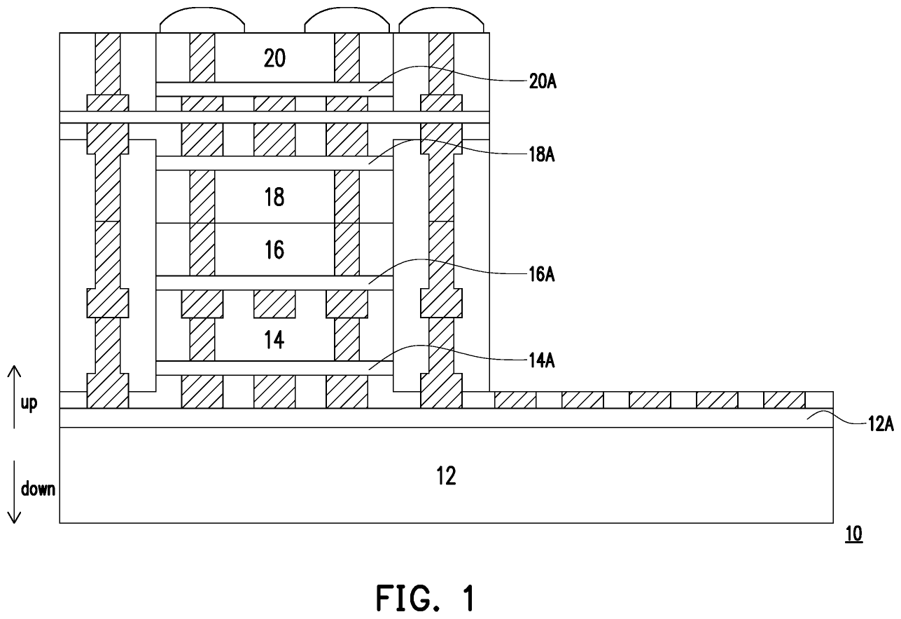

FIG. 1 is a drawing, schematically illustrating the 3D package structure of the semiconductor chips by face-to-face, face-to-back and back-to-back, according to an embodiment of the disclosure. Referring to FIG. 1, a semiconductor device 10 with a 3D package structure in an example includes a semiconductor chip 12 with a larger size and multiple semiconductor chips 14, 16, 18 and 20 with a smaller size as an example. A quantity of the smaller semiconductor chips 14, 16, 18 and 20 stacking on the semiconductor chip 12 may be changed based on the product design and the semiconductor chip 12 may adopt other semiconductor chips in different areas without limiting to the structure depicted in the embodiment of FIG. 1. The 3D packaging technology has been proposed in various stack structure, such as system-on-integrated-chips (SoIC) package, wafer-on-wafer (WoW) package, and chip-on-wafer (CoW) package. Some of the embodiments of the disclosure is based on the 3D packaging technology, but not limited to the types of the 3D packaging structures.

The semiconductor chips 12, 14, 16, 18 and 20 respectively includes a circuit layer 12A, 14A, 16A, 18A and 20A formed at the front sides thereof while the side opposite to the front side is known as the back side. The stacking of the semiconductor chips 12, 14, 16, 18 and 20 connected in the thickness direction may be categorized based on the facing of the front sides of the semiconductor chips 12, 14, 16, 18 and 20. For example, a face to face (F2F) stacking is achieved by the front side of one semiconductor chip facing the front side of the next semiconductor chip, a face to back (F2B) stacking is achieved by the front side of one semiconductor chip facing to the back side of the next semiconductor chip, and a back to back (B2B) stacking is achieved the back side of one semiconductor chip facing the back side of the next semiconductor chip.

In the embodiment, the semiconductor chip 12 is oriented facing up, the semiconductor chip 14 is oriented facing down, the semiconductor chip 16 is oriented facing down, the semiconductor chip 18 is oriented facing up and the semiconductor chip 20 is oriented facing down. Accordingly, the stacking between the semiconductor chip 12 and the semiconductor chip 14 is in the F2F manner, the stacking between the semiconductor chip 14 and the semiconductor chip 16 is in the F2B manner, the stacking between the semiconductor chip 16 and the semiconductor chip 18 is in the B2B manner, and the stacking between the semiconductor chip 18 and the semiconductor chip 20 is in the F2F manner. However, the disclosure is not just limited to the example. Each of the semiconductor chips 12, 14, 16, 18 and 20 may adopt the interface as the following descriptions and may be connected to the next one through any of the stacking manners selected from face-to-face, face-to-back and back-to-back.

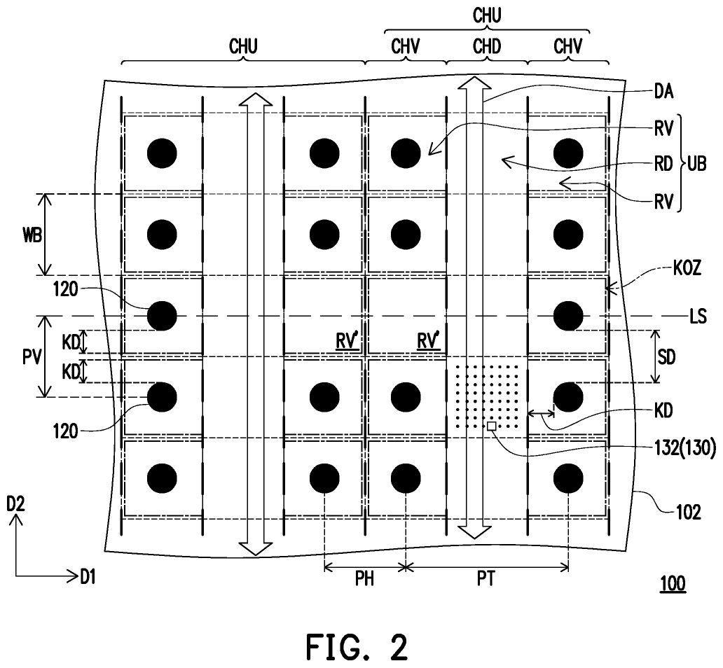

FIG. 2 schematically illustrates a plane view of an interface for a semiconductor chip in accordance with some embodiments of the disclosure. An interface 100 for a semiconductor chip 102 includes a plurality of bonds 120. The interface 100 has device layout channels CHD and via layout channels CHV, wherein each of the device layout channels CHD is located between two of the via layout channels CHV in a first direction D1 to form a unit layout channel CHU. In other words, each of the unit layout channels CHU is defined by two via layout channels CHV located at two opposite sides of the device layout channel CHD in the first direction D1. The bonds 120 are arranged in a bond map following the via layout channels CHV and outside the device layout channels CHD. In the embodiment, each of the unit layout channels CHU, each of the via layout channel CHV and each of the device layout channels CHD may extend linearly in a second direction D2 intersecting the first direction D1. In some embodiments, the first direction D1 and the second direction D2 may be perpendicular to each other, but the disclosure is not limited thereto.

In some embodiments, each of the bonds 120 is implemented by a through-silicon via. For example, the bonds 120 may be formed by a conductive material such as conductive metal and has a pillar-like structure extending in the thickness direction of the semiconductor chip 102 which may be perpendicular to the first direction D1 and the second direction D2.

In addition, the semiconductor chip 102 includes a circuitry and routing structure 130 and at least a portion of the circuitry and routing structure 130 may be disposed in the device layout channels CHD. In some embodiments, the circuitry and routing structure 130 may include a plurality of electronic components 132, a plurality of routing patterns (not shown), or a combination thereof. In some embodiments, the electronic components 132 may include active components, passive components or the like. For example, the active components may include transistors or the like and the passive components may include capacitors, resistors, or the like. The electronic components 132 in the circuitry and routing structure 130 may be connected to construct required circuitry and/or function through the routing patterns (not shown). In some embodiments, the portion of the circuitry and routing structure 130 disposed in the device layout channels CHD may include only the routing patterns (not shown) rather than the electronic components 132 based on various designs.

The bonds 120 in each of the via layout channels CHV may be arranged in one line in the second direction D2. Specifically, the bonds 120 in one via layout channel CHV may be closely arranged in the second direction D2 that is the extending direction of the via layout channel CHV. In some embodiments, a design rule of the interface 100 stipulates a predetermined smallest pitch of the bonds 120 and a vertical pitch PV of the bonds 120 in the second direction D2 may be an integer times of the predetermined smallest pitch. For example, the vertical pitch PV of most adjacent two of the bonds 120 in the second direction D2 may be equal to the predetermined smallest pitch so as to achieve a small bond pitch design. In some embodiments, the predetermined smallest pitch may be several microns, for example 10 μm or less than 10 μm, based on the design rule of the interface 100, but the disclosure is not limited thereto. In addition, two bonds 120 at two opposite sides of the device layout channel CHD in the first direction D1 may be arranged in a transversal pitch PT, and the transversal pitch PT is greater than the vertical pitch PV. In some embodiments, the transversal pitch PT may be sufficient to keep the space for the device layout channel CHD. Herein, the term “pitch” may be understood as a distance between the geometric centers of two adjacent elements. In some embodiments, the “most adjacent two” of the bonds 120 may be understood as two bonds 120 closely arranged and the circuitry and routing structure 130 being absent in the gap between the two bonds 120.

The unit layout channels CHU of the interface 100 are arranged side by side in the first direction D1. In some embodiments, the via layout channel CHV of one unit layout channel CHU is next to the via layout channel CHV of the next unit layout channel CHU so that the via layout channel CHV in one unit layout channel CHU may be immediately next to the via layout channel CHV in the next unit layout channel CHU in the first direction D1. In some embodiments, two bonds 120 of two adjacent unit layout channels CHU may be closely arranged in a horizontal pitch PH in the first direction D1. The horizontal pitch PH in the first direction D1 may be equal to the predetermined smallest pitch under the design rule of the interface 100 so as to achieve a small bond pitch design. That is, in some embodiments, the vertical pitch PV may be identical to or an integer multiple of the horizontal pitch PH.

In some embodiments, each of the unit layout channels CHU may be divided into a plurality of unit blocks UB in the second direction D2. The via layout channel CHV in each of the unit blocks UB forms a via region RV and the device layout channel CHD in each of the unit blocks UB forms a device region RD. Accordingly, each of the unit blocks UB includes one device region RD and two via regions RV located at two opposite sides of the device region RD in the first direction D1. In the drawings, the thin dash lines present the boundaries of the device regions RD and the via regions RV, the thick dash lines present the boundaries of the device layout channels CHD and the via layout channels CHV, and the thin dash lines and the thick dash lines are phantom lines for indicating the distributions of the respective regions and channels and are not limited to specific structural feature.

In some embodiments, the dimension of the unit block UB in the second direction D2 may be defined based on the vertical pitch PV of the bonds 120 so as to achieve the small bond pitch requirement. For example, the width WB of each of the unit blocks UB may be equal to the vertical pitch PV and each of the bonds 120 in each unit block UB may be located at the center of the corresponding unit block UB in the second direction D2. Each of the via regions RV is suitable to accommodate one of the bonds 120 and each of the via layout channel CHV is suitable to accommodate the bonds 120 arranged in one single line.

In some embodiments, each of the bonds 120 may be implemented by a through-silicon via which extending in the thickness direction. In the embodiment, a keep-out zone KOZ surrounding each of the bonds 120 is required so that the damage due to the stress caused by the formation of the through-silicon vias (the bonds 120) may be avoided. The keep-out zone KOZ may be demarked that the boundary of the keep-out zone KOZ is spaced from the edge of the bond 120 by a keep-out distance KD and the keep-out distance KD may be determined by the design rule of the interface 100. In the drawings of the disclosure, the short-long dash lines represent the boundaries of the keep-out zones KOZ for descriptive purpose and the short-long dash lines are photon line and not limited to specific structural features. In the embodiment, the circuitry and routing structure 130 is disposed outside the keep-out zone KOZ so as to be laterally spaced from the bonds 120 by a distance not smaller than the keep-out distance KD of the bonds 120. Similarly, each of the bonds 120 is disposed outside the keep-out zone KOZ of another of the bonds 120. For example, two immediately adjacent bonds 120 in the second direction D2 are spaced from each other by a sufficient spacing distance SD. In some embodiments, the vertical pitch PV of the bonds 120 may be stipulated by the design rule of the interface 100 that the spacing distance SD between the two immediately adjacent bonds 120 in the second direction D2 is greater than twice of the keep-out distance KD. In some alternative embodiments, the spacing distance SD between the two immediately adjacent bonds 120 in the second direction D2 may be substantially equal to twice of the keep-out distance KD to achieve a small bond pitch.

In each of the unit blocks UB, the device region RD for arranging the circuitry and routing structure 130 is located between two via regions RV for arranging the bonds 120. The circuitry and routing structure 130 in one device region RD may be electrically connected to either of the corresponding bonds 120 in the two via regions RV at the two opposite sides. Therefore, the layout flexibility of the circuitry and routing structure 130 is increased. In addition, the unit blocks UB are so arranged that the device regions RD are continuously connected in the second direction D2 to form the device layout channel CHD and no bond 120 is disposed within the device layout channel CHD. Therefore, the layout spacing of the circuitry and routing structure 130 is large and compactable for various layout designs.

In the embodiment, the bonds 120 may be exclusively arranged in the via layout channels CHV outside the device layout channel CHD, and the device regions RD are continuously connected in the second direction D2 to form the device layout channel CHD, so that the device layout channel CHD provides a large and adaptive layout spacing as indicated by the double arrow DA without being blocked by the bonds 120. The components of the circuitry and routing structure 130 in different device regions RD of the device layout channel CHD may be connected to construct the required circuitry.

In the embodiment, the interface 100 includes the regions such as the via regions RV and the device region RD arranged in a 5×6 array, wherein the via regions RV are arranged in the first, the third, the fourth and the sixth columns of the 5×6 array and the device regions RD are arranged in the second and the fifth columns of the 5×6 array. In addition, each column of the 5×6 array include 5 regions. Therefore, the interface 100 may provide 20 via regions RV in the first, the third, the fourth and the sixth columns of the 6×5 array. In the embodiments, 20 via regions RV are provided for the disposition of the bonds 120 while the device layout channels CHD provides a large and continuous layout spacing for the disposition of the circuitry and routing structure 130. In some embodiments, a portion of the circuitry and routing structure 130 located in one row may be electrically connected to another portion of the circuitry and routing structure 130 located in another row in the same device layout channel CHD, such that the utilization of the layout spacing is flexible.

In some embodiments, various density designs of the bonds 120 may be achieved without changing the layout spacing of the device layout channel CHD and the arrangement of the via regions RV. For example, a quantity of the bonds 120 may be less than a quantity of the via regions RV so that a design of less bond density is achieved. In some alternative embodiments, a quantity of the bonds 120 may be equal to a quantity of the via regions RV so as to achieve a design of higher bond density. In the embodiment, the via channels CHV are the first, the third, the fourth, and the sixth columns of the 5×6 array, each row of the 5×6 array includes four via regions RV respectively located in the via channels CHV and each via channel CHV of the 5×6 array includes five via regions RV, such that twenty via regions RV are provided. In the case that the bond density is required to be large, each of the twenty via regions RV may be occupied by one bond 120. In the case that the bond density is required to be less, one or more of the via regions RV may be absent of the bonds. In some embodiments, the via regions RV in one or more rows of the 5×6 array may be absent of the bonds 120 to achieve a less bond density. In some embodiments, the via regions RV in one or more of the via channels CHV of the 5×6 array may be absent of the bonds 120 to achieve a less bond density. In addition, in some embodiments, the via regions RV absent of the bonds 120 may be discretely distributed in the via channels CHV of the 5×6 array to achieve the required bond density, such that in the same row or via channels CHV of the 5×6 array, one or more of the via regions RV may be absent of the bonds 120 while the other of the via regions RV are occupied by the bonds 120. Accordingly, the interface 100 may achieve an optimized bond map configuration through skipping the disposition of the bonds 120 in one or more rows of the 5×6 array, skipping the disposition of the bonds 120 in one or more of the via channels CHV, skipping the disposition of the bonds 120 in one or more via regions VR in one or more row of the 5×6 array, and/or skipping the disposition of the bonds 120 in one or more via regions VR in one or more via channels CHV. In some embodiments, the interface 100 having totally i via regions VR is applicable to various bond densities for disposing j bonds 120, wherein j is from 1 to i and i and j are integers.

In FIG. 2, the quantity of the bonds 120 is less than the quantity of the via regions RV to achieve a smaller bond pitch and for example, the via regions indicated by RV′ are absent of the bonds 120. Therefore, the arrangement of the bonds 120 may construct a bond map following the via region arrangement, but the bond map may be different from the via region arrangement since one or more of the via regions VR may be absent of the bonds 120 due to the bond density design. In some embodiments, the circuitry and routing structure 130 may also be arranged in the via regions RV′ absent of the bonds 120 so as to further increase the layout spacing of the circuitry and routing structure 130. Accordingly, the interface 100 may provide a larger layout spacing for the circuitry and routing structure 130 when the quantity of the bonds 120 is reduced.

In the embodiment, the bonds 120 may be arranged in the interface 100 in a symmetric manner. For example, the bonds 120 may be arranged symmetrically with respect to the reference line LS passing through the third row of the 6×5 array. The interface 100 may have the same bond map after being flipped upside down along the reference line LS, which is applicable for forming various 3D (three-dimensional) package structures that include stacked multiple semiconductor chips and/or wafers. For example, the interface 100 is applicable to the semiconductor chips 12 to 20 of the semiconductor device 10 depicted in FIG. 1 which are stacked in the F2B manner, the B2B manner and the F2F manner without changing the bond map for the bonds 120.

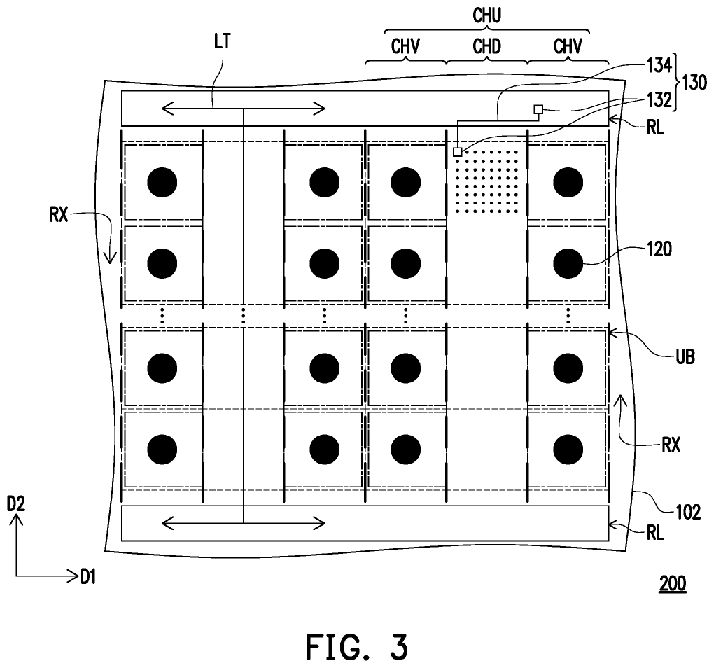

FIG. 3 schematically illustrates a plane view of an interface for a semiconductor chip in accordance with some embodiments of the disclosure. The interface 200 implemented in the semiconductor chip 102 includes a plurality of bonds 120, and the semiconductor chip 102 includes a circuitry and routing structure 130, which are similar to the corresponding elements in the previous embodiment and thus the details of the respective elements in the embodiments may be refer to each other. In the embodiment, the interface 200 further has a transversal layout region RL extending in the first direction D1 and arranged at a side of the unit layout channels CHU in the second direction D2. A portion of the circuitry and routing structure 130 may be disposed in the transversal layout region RL. The circuitry and routing structure 130 may construct the required logic circuitry and the electronic components 132 disposed in the transversal layout region RL may be electrically connected to the electronic components 132 disposed in the device layout channel CHD.

In some embodiments, the electronic components 132 disposed in the device layout channel CHD and the electronic components 132 disposed in the transversal layout region RL may be connected through the routing patterns, for example the routing pattern 134, and the required logic circuitry may be constructed by the electronic components 132 disposed in the device layout channel CHD, the electronic components 132 disposed in the transversal layout region RL, or a combination thereof. In some embodiments, one or more of the device layout channels CHD may be absent of the electronic components 132 of the circuitry and routing structure 130 while only the routing patterns of the circuitry and routing structure 130 are arranged in the one or more of the device layout channels CHD based on various layout designs.

The device layout channel CHD extends in the second direction D2 and provide a layout spacing connected to the transversal layout region RL. No bonds 120 is disposed in the device layout channel CHD so that the circuitry constructed by the electronic components 132 in the device layout channel CHD is connected to the electronic components 132 disposed in the transversal layout region RL without difficulty such as without the block of the bonds 120. In some embodiments, the regions at two opposite sides of one unit layout channel CHU in the second direction D2 may both serve as the transversal layout regions RL to form a I-shape layout spacing for the circuitry and routing structure 130. In some embodiments, the transversal layout region RL may be arranged at one side of the unit layout channel CHU in the second direction D2 to form a normal or inverted T-shape layout spacing for disposing the circuitry and routing structure 130. Therefore, the components of the circuitry and routing structure 130 can be freely arranged along the layout spacing trace LT indicated in FIG. 3. Comparably, the bonds 120 closely arranged in the via layout channels CHV may block and/or limit the layout trace for the circuitry and routing structure 130 in the first direction D1. Therefore, the regions RX at the opposite sides of the interface 200 in the first direction D1 may be inappropriately served as the layout spacing for the circuitry and routing structure 130.

The interface 200 may provide large and adaptive layout spacing for constructing required circuitry and/or function even if the pitch of the bonds 120 is shrunk, similar to the interface 100. In some embodiments, the interface 200 may be compactable to various bond density requirement. For example, the interface 200 may achieve an optimized bond map configuration through skipping the disposition of the bonds 120 in one or more rows of the 5×6 array, skipping the disposition of the bonds 120 in one or more of the via channels CHV, skipping the disposition of the bonds 120 in one or more via regions VR in one or more row of the 5×6 array, and/or skipping the disposition of the bonds 120 in one or more via regions VR in one or more via channels CHV. Alternatively, all the via regions RV in the interface 200 may be disposed with the bonds 120 to achieve a large bond density. In some embodiments, the interface 200 having totally i via regions VR is applicable to various bond densities for disposing j bonds 120, wherein j is from 1 to i and i and j are integers. In the interface 100 and the interface 200, a quantity of the unit blocks UB in each of the unit layout channels CHU may be changed based on the required circuitry and/or function of the interface 100/200. For example, more rows of the unit blocks UB connected in the second direction D2 may be arranged for a larger layout spacing requirement of the interface 100/200. In some embodiment, the design of the unit blocks UB may achieve a symmetric arrangement of the bonds 120 so that the interface 100/200 is applicable for the semiconductor device involving various stacking manners such as F2B, B2B or F2F.

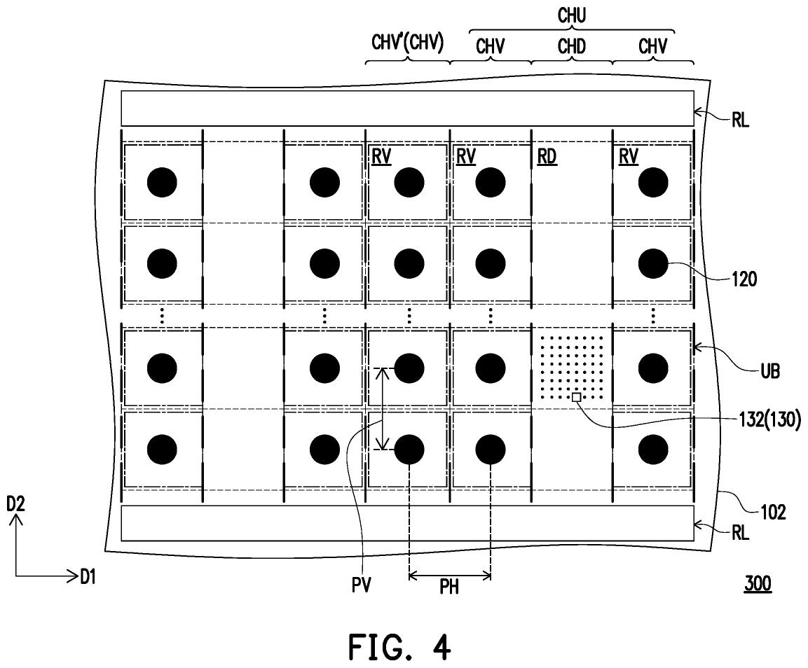

FIG. 4 schematically illustrates a plane view of an interface of a semiconductor device in accordance with some embodiments of the disclosure. The interface 300 implemented in the semiconductor chip 102 includes a plurality of bonds 120, and the semiconductor chip 102 includes a circuitry and routing structure 130, which are similar to the corresponding elements in the previous two embodiment and thus the details of the respective elements in the embodiments may be refer to each other. In the embodiment, the interface 300 further has a transversal layout region RL which is similar to the transversal layout region RL of the interface 200. In addition, the via layout channels CHV in the interface 300 include an individual via layout channel CHV′ independent from the unit layout channel CHU. For example, one of the via layout channels CHV arranged between two of the unit layout channels CHU in the first direction D1 is indicated as the via layout channel CHV′ in FIG. 4. In some embodiments, the unit layout channel CHU and the individual via layout channel CHV′ may be alternately arranged in the first direction D1.

As shown in FIG. 4, the arrangement of the bonds 120 in the via layout channel CHV′ is similar to that in each of the via layout channels CHV in the unit layout channel CHU. For example, the via layout channel CHV′ includes a plurality of via regions RV arranged in the second direction D2 and one bond 120 is disposed in one of the via regions RV of the via layout channel CHV′. In some embodiments, two adjacent bonds 120 of the via layout channel CHV′ and the adjacent via layout channel CHV in the first direction D1 may be arranged in a horizontal pitch PH and two adjacent bonds 120 of the via layout channel CHV′ in the second direction D2 may be arranged in a vertical pitch PV. In some embodiments, the horizontal pitch PH and the vertical pitch PV with respect to the bonds 120 in the via layout channel CHV′ may be equal to the predetermined smallest pitch under the design rule of the interface 300.

The bonds 120 are configured to transmit various types of electric signals such as data signals, power signal and ground signal. In some embodiments, the bonds 120 in the via regions RV of the unit layout channel CHU may transmit the data signals and one or more of the bonds 120 in the via regions RV of the via layout channel CHV′ may transmit the power signal, the ground signal, and/or the data signals. In some alternative embodiments, one or more of the bonds 120 in the via regions RV of the unit layout channel CHU may also transmit the power signal and/or the ground signal. In some embodiments adopting to the design of the interface 100 or 200, the bonds 120 in the via regions RV of the unit layout channel CHU may respectively transmit the data signals, the power signal and the ground signal. The type of the signal that the bonds 120 transmit may be determined by the wiring path of the circuitry and routing structure 130 in the interface 100/200/300 without changing the via region arrangement for disposing the bonds 120. In some embodiments, a quantity of the bonds 120 disposed in the via layout channels CHV and CHV′ may be determined based on the design requirements. For example, one or more of the via regions RV in the via layout channels CHV and CHV′ may be absent of the bonds 120 to achieve a smaller bond density design. Therefore, the bond map constructed by the arrangement of the bonds 120 may be different from the via region arrangement but follow the via region arrangement. Similar to the previous embodiments, the via regions RV absent of the bonds 120 may serve as additional layout spacing for arranging the circuitry and routing structure so that a larger layout spacing may be provided.

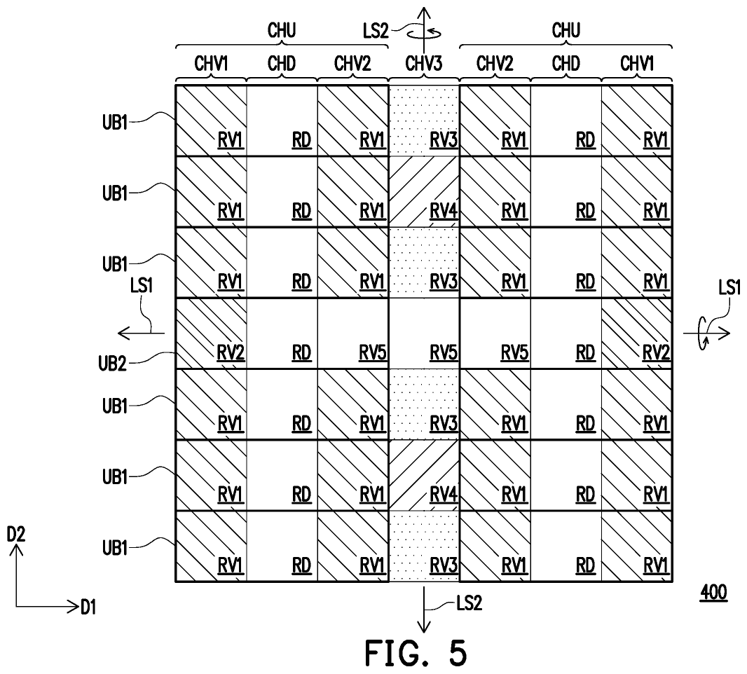

FIG. 5 schematically illustrates an interface for a semiconductor chip in accordance with some embodiments of the disclosure. FIG. 5 schematically presents the region arrangement of the interface without showing the details of the structures in each region for descriptive purpose and the details of the structures in each region may refer to the other embodiments in the disclosure. The interface 400 for a semiconductor chip in the embodiment has a plurality of device regions RD and a plurality of via regions RV1˜RV5.

In the embodiment, the via regions RV1˜RV5 all represent the regions for disposing the bonds and may involve different functions so that the via regions are indicated by different numerical numbers for descriptive purpose. For example, the bonds for transmitting the first type of electric signal are disposed in the via regions RV1, the bonds for transmitting the second type of electric signal are disposed in the via regions RV2, the bonds for transmitting the third type of electric signal are disposed in the via regions RV3, the bonds for transmitting the fourth type of electric signal are disposed in the via regions RV4, and no bond is formed in the via regions RV5.

Specifically, in FIG. 5, the via regions RV1 are filled with backslash patterns, the via regions RV2 are filled with double backslash patterns, the via regions RV3 are filled with dot patterns, and the via regions RV4 are filled with slash patterns while the regions such as the via regions RV5 and the device regions RD without disposed with the bonds are blank. Accordingly, the arrangement of the via regions RV1, RV2, RV3 and RV4 may construct the bond map in the embodiment. It is seen that the bond map is not identical to the via region arrangement but follows the via region arrangement.

In the embodiment, two of the via regions RV1 are arranged at opposite sides of one device region RD in the first direction D1 to form a unit block UB1, and one via region RV2 and one via region RV5 are arranged at opposite sides of one device region RD in the first direction D1 to form a unit block UB2. Three unit blocks UB1, one unit block UB2 and another three unit block UB1 are connected continuously in the second direction D2 to form a unit layout channel CHU. The interface 400 includes two unit layout channels CHU, but the disclosure is not limited thereto.

As shown in FIG. 5, the via regions RV1 to RV5 and the device regions RD are arranged in a 7×7 array. Specifically, three via regions RV1, one via region RV2 and another three via regions RV1 arranged in line is defined as the via layout channel CHV1; three via regions RV1, one via region RV5 and another three via regions RV1 arranged in line is defined as the via layout channel CHV2; and the via region RV3, the via region RV4, the via region RV3, the via region RV5, the via region RV3, the via region RV4, and the via region RV3 arranged in line is defined as the via layout channel CHV3. As shown in FIG. 5, each of the via layout channel CHV1, the via layout channel CHV2 and the via layout channel CHV3 provide a symmetric arrangement with respect to the reference line LS1. In addition, in the first direction, the via layout channel CHV1, the device layout channel CHD, the via layout channel CHV2, the via layout channel CHV3, the via layout channel CHV2, the device layout channel CHD, and the via layout channel CHV1 are arranged in sequence so as to provide a symmetric arrangement with respect to the reference line LS2. Accordingly, the interface 400 has a symmetric bond map with respect to the reference line LS1 as well as the reference line LS2.

Due to the symmetric bond map, the interface 400 may be applicable to any of the semiconductor chips 12 to 20 in the semiconductor device 10 as shown in FIG. 1. For example, when the interface 400 is applied to the semiconductor chip 12 oriented facing up, the interface 400 presents the bond map as shown in FIG. 5 from a top view direction, while when the interface 400 is applied to the semiconductor chip 14 oriented facing down, the interface 400 also presents the bond map as shown in FIG. 5 from the top view. Therefore, the semiconductor chip 12 and the semiconductor chip 14 can be stacked in the F2F manner while both utilize the design of the interface 400. Similarly, the interface 400 may be applicable to the semiconductor chips 16, 18 and 20 in FIG. 1 that involves various types of stacking manners for a 3D package structure.

In the embodiment, the device regions RD of the device layout channels CHD are continuously arranged along the second direction D2 and are absent of the bonds so as to provide a large and adaptive layout spacing for disposing the circuitry and routing structure as disclosed in other embodiments of the disclosure. In addition, the circuitry and routing structure may be further arranged in the via regions RV5 since the via region RV5 is also absent of the bonds. Therefore, the interface 400 may provide H-shape layout spacing for the circuitry and routing structure, which is adaptive to various circuitry designs.

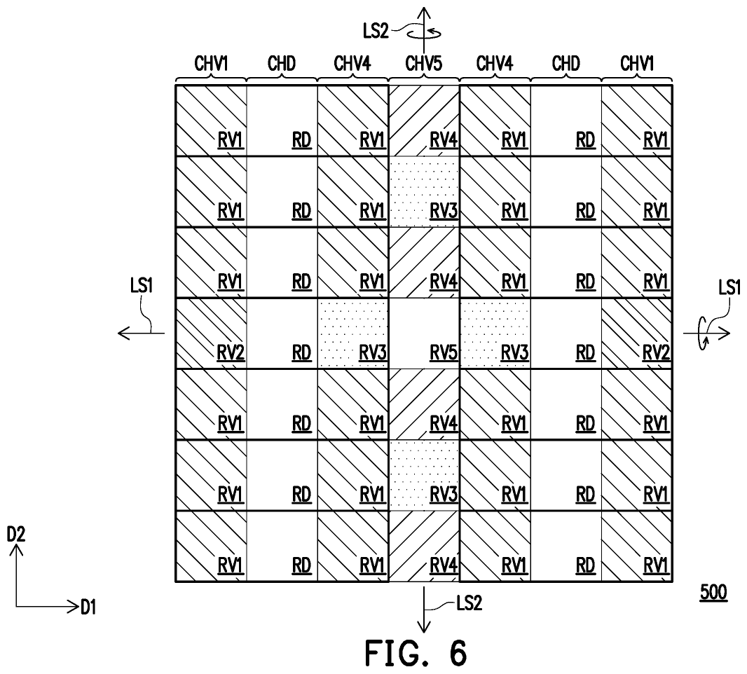

FIG. 6 schematically illustrates an interface for a semiconductor chip in accordance with some embodiments of the disclosure. FIG. 6 schematically present the region arrangement of the interface without showing the details of the structures in each region for descriptive purpose and the details of the structures in each region may refer to the previous embodiments. The interface 500 includes the via regions RV1 to RV5 and the device regions RD arranged in a 7×7 array as an example. The functions of the via regions RV1 to RV5 may refer to the interface 400 and similarly, the regions filled with patterns in FIG. 6 may construct the bond map that follows, but is not identical to, the via region arrangement. The via layout channels CHV1 and the device layout channels CHD in the embodiment are the same as those disclosed in the embodiment of FIG. 5. Different from the embodiment of FIG. 5, in the interface 500, the via regions RV1 and the via regions RV3 arranged in the third and the fifth column in the 7×7 array form a via layout channel CHV4. In addition, the via regions RV3 and RV4 and the via region RV5 arranged in the fourth column of the 7×7 array form the via layout channel CHV5.

In the via layout channel CHV4, the via regions RV3 is arranged in the fourth row of the 7×7 array to achieve a symmetric arrangement with respect to the reference line LS1. In the via layout region CHV5, the via regions RV3 and RV4 are symmetrically arranged at two opposite sides of the via region RV5 in the fourth column of the 7×7 array to achieve a symmetric arrangement with respect to the reference line LS1. Referring to the previous embodiment, the via layout channels CHV1 involves a symmetric arrangement with respect to the reference line LS1. Accordingly, the interface 500 has a symmetric bond map with respect to the reference line LS1.

In addition, the region arrangement of the interface 500 includes one via layout channel CHV1, one device layout channel CHD, one via layout channel CHV4, one via layout channel CHV5, another via layout channel CHV4, another device layout channel CHD, and another via layout channel CHV1 are arranged in sequence in the first direction D1 to present a symmetric arrangement with respect to the reference line LS2. Therefore, the interface 500 also has a symmetric bond map with respect to the reference line LS2. The interface 500 may be applicable to all of the semiconductor chips 12, 14, 16, 18 and 20 of the semiconductor device 10 depicted in FIG. 1.

FIG. 5 and FIG. 6 are the exemplary examples showing the symmetric bond maps for descriptive purpose, but the disclosure is not limited thereto. The interface 400 includes four via regions RV3 and two via regions RV4, and the interface 500 includes four via regions RV3 and four via regions RV4 so that the interfaces 400 and 500 provide various bond density designs and various bond maps under the same via region arrangement. Therefore, the via region arrangement in accordance with the embodiments of the disclosure provides better layout spacing utilization for the circuitry and routing structure, is compactable for various bond density designs and is applicable to various stacking manner, e.g. F2F, F2B, B2B, etc.

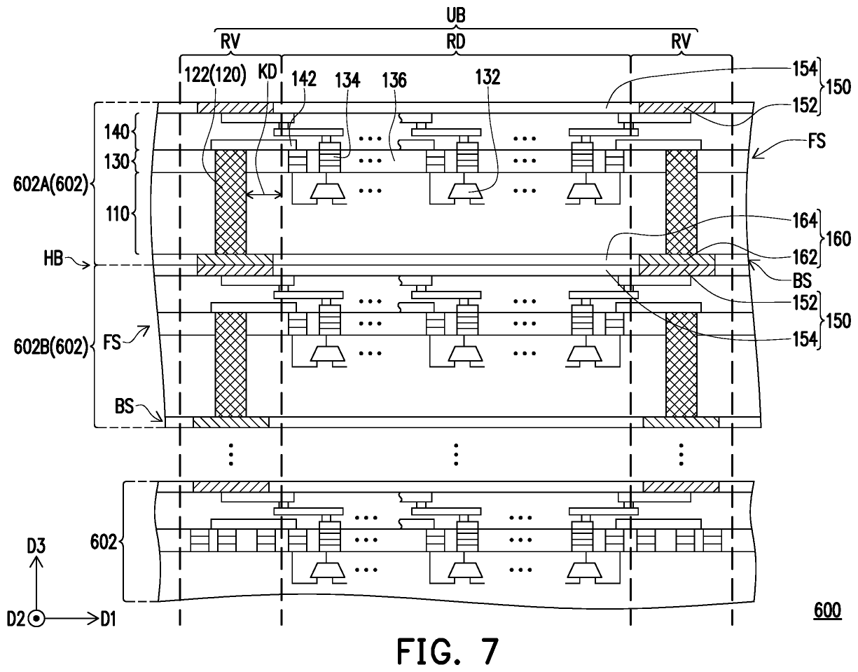

FIG. 7 schematically illustrates a portion of a semiconductor device in accordance with some embodiments of the disclosure. A semiconductor device 600 includes a plurality of semiconductor chips 602 with respective interfaces, and one of the semiconductor chips 602 is stacked to another of the semiconductor chips 602 through a hybrid bond interface HB. Each of the semiconductor chip 602 includes a substrate 110, a plurality of through-silicon vias 122 implementing the bonds 120 described in the previous embodiments, a circuitry and routing structure 130, a metallization structure 140, a front side interface structure 150 and a back side interface structure 160. In each of the semiconductor chips 602, the bonds 120 may construct an interface served as an exemplary implementation of the interface 100 to 500 described in the previous embodiments and thus the details of the arrangements of the bonds 120 and the circuitry and routing structure 130 described in the previous embodiments are able to be incorporated to and applied to the embodiment.

Specifically, a device region RD located between two of the via regions RV in the first direction D1 may be defined to from a unit block UB. Similar to the previous embodiments but not presented in FIG. 7, a plurality of unit blocks UB may be arranged continuously in a second direction D2 intersecting the first direction D1 so that the unit layout channel CHU described in the previous embodiments is defined. The through-silicon vias 122 extend through the substrate 110, and each of the through-silicon vias 122 located in one of the via regions RV. The through-silicon vias 122 are disposed outside the device region RD. The circuitry and routing structure 130 is disposed on the substrate 110 and includes a plurality of electronic components 132 and a plurality of routing patterns 134 disposed in the device regions RD. The substrate 110 has a front side FS at which the circuitry and routing structure 130 is formed and a back side BS which is opposite to the front side FS in a third direction D3, i.e. the thickness direction of the substrate 110.

The circuitry and routing structure 130 is disposed at the front side FS of the substrate 110. The circuitry and routing structure 130 includes a plurality of electronic components 132 for construct required circuitry and/or function and also includes a plurality of routing patterns 134 connected to the electronic components 132. The substrate 110 may be a semiconductor substrate or a semiconductor substrate inclusive of isolation regions and the electronic components 132 of the circuitry and routing structure 130 may be partially integrated in the substrate 110. In some embodiments, the electronic components 132 may include active components, passive components or the like. For example, the active components may include transistors or the like and the passive components may include capacitors, resistors, or the like. In some embodiments, the routing patterns 134 may be conductive patterns formed by conductive metal layers between multiple dielectric layers 136 to establish various electric transmission paths to connect the electronic components 132. In some embodiments, the routing patterns 134 and the electronic components 132 are laterally spaced from the through-silicon vias 122 by at least the keep-out distance KD. The dielectric layers 136 may continuously extend from the device region RD to the via region RV. Each of the through-silicon vias 122 extends from the front side FS of the substrate 110 to the back side BS of the substrate 110. In addition, the through-silicon vias 122 also extend through the dielectric layers 136 formed at the front side FS of the substrate 110.

The metallization structure 140 is disposed on the circuitry and routing structure 130 and electrically connecting the bonds 120 and the electronic components 132. In some embodiments, the metallization structure 140 includes a conductive pattern 142 continuously extending from one of the via regions RV to one of the device regions RD. Accordingly, the electronic components 132 may be electrically connected to the corresponding bond 120 by the conductive pattern 142. The metallization structure 140 is understood as an interconnection structure which provides various electric transmission paths for the electronic components 132 and the bonds 120. For example, the metallization structure 140 may establish the electric transmission path for electrically connecting one of the electronic components 132 to one of the bonds 120. In addition, the metallization structure 140 may also establish the electric transmission path for electrically connecting one of the bonds 120 to an external device. In some embodiments, the type of the signal that the bonds 120 transmit may be determined by the wiring path of the metallization structure 140.

In some embodiments, the front side interface structure 150 is disposed at an outer side of the metallization structure 140 that is away from the circuitry and routing structure 130 for bonding to an external device such as another semiconductor chip or another substrate. The front side interface structure 150 includes metal patterns 152 and dielectric patterns 154. The metal patterns 152 and the dielectric patterns 154 are alternately exposed at the same plane. In addition, the back side interface structure 160 is disposed at the back side BS of the substrate 110. The back side interface structure 160 includes metal patterns 162 and dielectric patterns 164 alternately exposed at the same plane. The metal patterns 152 of the front side interface structure 150 and the metal patterns 162 of the back side interface structure 160 may be electrically connected to the corresponding through-silicon vias 122 implementing the bonds 120 so that the electric transmission path extends in the third direction D3 through the semiconductor chip 602 is established. In some embodiments, the metal patterns 152 and the metal patterns 162 may be or comprise copper and/or some other suitable metal(s) and the dielectric patterns 154 and the dielectric patterns 164 may be or comprise, for example, silicon oxide and/or some other suitable dielectric(s).

In the embodiments, three or more semiconductor chips 602 are stacked in the third direction D3 intersecting the first direction D1 and the second direction D2. For example, two of the semiconductor chips 602 indicated by the semiconductor chip 602A and the semiconductor chip 602B are described as an example. In FIG. 7, the semiconductor chip 602A and the semiconductor chip 602B are bonded to and stacked on each other. In the embodiment, the metal patterns 162 in the back side interface structure 160 of the semiconductor chip 602A is in contact with the metal patterns 152 in the front side interface structure 150 of the semiconductor chip 602B. In addition, the dielectric patterns 164 in the back side interface structure 160 of the semiconductor chip 602A is in contact with the dielectric patterns 154 in the front side interface structure 150 of the semiconductor chip 602B. Therefore, the back side interface structure 160 of the semiconductor chip 602A and the front side interface structure 150 of the semiconductor chip 602B are bonded to each other to form the hybrid bonding interface HB. The hybrid bonding interface HB may include the structure of the metal patterns 152 bonded to the metal patterns 162 and the dielectric patterns 154 bonded to the dielectric patterns 164.

The semiconductor chip 602A and the semiconductor chip 602B are both oriented that the front side FS facing up and the back side BS facing down so that the semiconductor chip 602A and the semiconductor chip 602B are bonded to each other in a F2B manner. In other words, the front side interface structure 150 of the semiconductor chip 602B is bonded and in contact with the back side interface structure 160 of the semiconductor chip 602A. Each of the semiconductor chips 602A and 602B has the interface similar to or identical to one or more of the interfaces 100 to 500 described in the previous embodiments. In addition, the through-silicon vias 122 in the semiconductor chip 602A may be aligned with the through-silicon vias 122 in the semiconductor chip 602B in the third direction D3.

In alternative embodiments, the semiconductor chip 602A and the semiconductor chip 602B may be bonded to each other in a F2F manner that the front side FS of the semiconductor chip 602A faces the front side FS of the semiconductor chip 602B. For example, the semiconductor chip 602A in FIG. 7 may be oriented upside down so that the front interface structure 150 of the semiconductor chip 602A is bonded to and in contact with the front interface structure 150 of the semiconductor chip 602B under the F2F manner. The bonds 120 in both semiconductor chip 602A and the semiconductor chip 602B are arranged in the via regions RV located at two opposite sides of the device region RD and the via regions RV and the device region RD may adopt the region arrangements described in the previous embodiments. Therefore, similar to the previous embodiments, the bonds 120 in each of the semiconductor chip 602A and the semiconductor chip 602B may be symmetrically arranged, so that under the F2F manner, the bonds 120 of the semiconductor chip 602A may still be aligned with the bonds 120 of the semiconductor chip 602B. Accordingly, the arrangements of the unit block UB in the embodiment and the previous embodiments facilitate the design compatibility to various stacking manners. In addition, the design of the semiconductor chips 602 with any of the interfaces depicted in the previous embodiments may be applicable in a 3D package structure that requires the stack of multiple semiconductor chips, such as a chip-on-wafer (CoW) device, a wafer-to-wafer (WoW) device or the like.

In light of the foregoing, the interface for a semiconductor chip in accordance with some embodiments of the disclosure includes a plurality of unit blocks each of which is formed by one device region and two via regions located at two opposite side of the device region. The unit blocks are disposed next to one another in a linear direction to form unit layout channel that includes two via layout channels located at opposite sides of one device layout channel. Accordingly, the bonds are exclusively arranged in the corresponding via regions to be arranged closely by a predetermined smallest vertical pitch in the linear direction of the via layout channel, which helps to achieve a small bond pitch design. In some embodiments, the via regions with various functions may be arranged in a symmetric manner so that the interface is adaptive for the semiconductor chips to be stacked in various stacking manners such as F2B, F2F, or B2B without modifying the via region arrangement. In addition, the interface in accordance with some embodiments in the disclosure provides a large layout spacing such as the device layout channel for the circuitry and routing structure, which is adaptive for various the circuitry layout.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An interface for a semiconductor chip, having device layout channels and via layout channels, wherein each of the device layout channels is located between two of the via layout channels in a first direction to form a unit layout channel extending in a second direction intersecting the first direction, wherein the interface comprises:
a plurality of bonds, arranged in a bond map following the via layout channels and outside the device layout channels, wherein most adjacent two of the bonds in the second direction are arranged in a vertical pitch, two bonds located at two opposite sides of the device layout channel in the first direction are arranged in a transversal pitch, and the transversal pitch is greater than the vertical pitch,
wherein the semiconductor chip comprises a circuitry and routing structure, wherein at least a portion of the circuitry and routing structure is disposed in the device layout channels.

2. The interface for the semiconductor chip of claim 1, wherein one of the via layout channels is arranged between two of the unit layout channels in the first direction.

3. The interface for the semiconductor chip of claim 1, wherein the circuitry and routing structure comprises a plurality of electronic components, a plurality of routing patterns or a combination thereof, and the electronic components comprise at least one semiconductor component.

4. The interface for the semiconductor chip of claim 1, wherein the circuitry and routing structure is spaced from the bonds by a distance not smaller than a keep-out distance of the bonds.

5. The interface for the semiconductor chip of claim 4, wherein a spacing distance between the most adjacent two of the bonds in the second direction is greater than twice of the keep-out distance.

6. The interface for the semiconductor chip of claim 1, wherein the circuitry and routing structure is absent between the most adjacent two of the bonds in the second direction.

7. The interface for the semiconductor chip of claim 1, wherein the semiconductor chip further comprising a metallization structure disposed on the circuitry and routing structure and electrically connecting the bonds and the circuitry and routing structure.

8. The interface for the semiconductor chip of claim 7, wherein the metallization structure comprises a conductive pattern continuously extending from one of the via layout channels to one of the device layout channels.

9. The interface for the semiconductor chip of claim 1, wherein the unit layout channel is divided into unit blocks arranged in the second direction, each of the via layout channels in one of the unit blocks forms a via region, each of the device layout channels in one of the unit blocks forms a device region, and each of the unit blocks has a width in the second direction substantially identical to the vertical pitch of the bonds.

10. The interface for the semiconductor chip of claim 9, wherein each of the via regions accommodates one of the bonds.

11. The interface for the semiconductor chip of claim 9, wherein a quantity of the bonds is less than or equal to a quantity of the via regions and at least one of the via regions is absent of the bonds.

12. The interface for the semiconductor chip of claim 11, wherein another portion of the circuitry and routing structure is disposed in the at least one of the via regions absent of the bonds.

13. The interface for the semiconductor chip of claim 1, wherein the interface further has a transversal layout region extending in the first direction and arranged at a side of the unit layout channels in the second direction, and another portion of the circuitry and routing structure being disposed in the transversal layout region and electrically connected to the portion of the circuitry and routing structure disposed in the device layout channels.

14. The interface for the semiconductor chip of claim 1, wherein in each of the via layout channels, the bonds are arranged along the second direction in one single line.

15. A semiconductor device, comprising:
a plurality of semiconductor chips, one of the semiconductor chips being stacked to another of the semiconductor chips, and each of the semiconductor chips comprising an interface for the semiconductor chip having device regions and via regions, wherein each of the device regions is located between two of the via regions in a first direction to form a unit block, and each of the unit blocks is arranged next to one another in a second direction intersecting the first direction,
the interface comprises a plurality of bonds arranged in a bond map following the via regions and outside the device regions, wherein most adjacent two of the bonds in the second direction are arranged in a vertical pitch, and the vertical pitch is substantially equal to a width of each of the unit blocks in the second direction, and
the each of the semiconductor chips comprises a circuitry and routing structure, wherein a portion of the circuitry and routing structure is disposed in the device regions.

16. The semiconductor device of claim 15, wherein the semiconductor chips are stacked in a third direction intersecting the first direction and the second direction.

17. The semiconductor device of claim 15, wherein the circuitry and routing structure is disposed at a front side of the each of the semiconductor chips and each of the bonds comprises a through silicon via extending from the front side to a back side of the each of the semiconductor chips.

18. The semiconductor device of claim 17, wherein the bonds are arranged in the via regions to form a symmetric bond map.

19. The semiconductor device of claim 18, wherein the front side of one of the semiconductor chips faces to the front side of next one of the semiconductor chips.

20. The semiconductor device of claim 18, wherein the front side of one of the semiconductor chips faces to the back side of next one of the semiconductor chips.

21. The semiconductor device of claim 15, wherein in each of the semiconductor chips, the bonds located at two opposite sides of one of the device regions are arranged in a transversal pitch in the first direction and the transversal pitch is greater than the vertical pitch.

22. The semiconductor device of claim 15, wherein the circuitry and routing structure is spaced from the bonds by a distance not smaller than a keep-out distance of the bonds.
